(19) United States
(12) Patent Application Publication
(10) Pub. No.: US 2017/0117888 A1
(43) Pub. Date: Apr. 27, 2017

(54) VOLTAGE COMPARISON CIRCUIT

(71) Applicant: Kabushiki Kaisha Toshiba, Tokyo (JP)

(72) Inventor: Hironori Nagasawa, Yokohama Kanagawa (JP)

(21) Appl. No.: 15/259,492

(22) Filed: Sep. 8, 2016

(30) Foreign Application Priority Data
Oct. 21, 2015 (JP) 2015-207290

(51) Int. Cl. H03K 5/24

(52) U.S. Cl. CPC H03K 5/2481

(57) ABSTRACT

According to one embodiment, the voltage comparison circuit includes: a first MOS transistor having a first gate applied with a first input voltage, a second MOS transistor having a second gate applied with a second input voltage compared with the first input voltage, a first current source connected in common to sources of the first and second MOS transistors, loads connected to drains of the first and the second MOS transistors, a third MOS transistor having a third gate connected to either one of the drains of the first and second MOS transistors, a logic inverter circuit connected to the drain of the third MOS transistor and generating a logic output based on a voltage difference between the first and second input voltages, and an additional circuit for controlling voltage of the node connected to the drain of the third MOS transistor, the second current source, and the first logic inverter circuit.

### CROSS-REFERENCE TO RELATED APPLICATIONS

This application is based upon and claims the benefit of priority from Japanese Patent Application NO. 2015-207290 filed on Oct. 21, 2015, the entire contents of which are incorporated herein by reference.

### FIELD

Embodiments described herein relate generally to voltage comparison circuits.

### BACKGROUND

Conventionally, voltage comparison circuits for comparing two input voltage values are known.

### BRIEF DESCRIPTION OF THE DRAWINGS

FIG. 1 is a circuit diagram showing an example of a voltage comparison circuit according to a first embodiment;

FIG. 2 is a circuit diagram showing an example of a voltage comparison circuit according to a second embodiment;

FIG. 3 is a timing chart showing output of the voltage comparison circuit according to the second embodiment;

FIG. 4 is a circuit diagram showing an example of a voltage comparison circuit according to a third embodiment;

FIG. 5 is a circuit diagram showing a voltage comparison circuit according to a comparative example; and

FIG. 6 is a timing chart showing output of the voltage comparison circuit according to the comparative example upon a rise of a power supply voltage Vdd0.

### DETAILED DESCRIPTION

A voltage comparison circuit, according to one embodiment, includes a first MOS transistor of a first conductivity type having a first gate applied with a first input voltage, a first source, and a first drain, a second MOS transistor of the first conductivity type having a second gate applied with a second input voltage which is compared with the first input voltage, a second source electrically connected to the first source, and a second drain, a first current source connected in common to the first source and the second source, loads connected to each of the first drain and the second drain, a third MOS transistor of a second conductivity type having a third gate connected to either the first drain or the second drain, a third source, and a third drain, a second current source connected to the third drain, a first logic inverter circuit connected to the third drain and generating a logic output based on a voltage difference between the first and second input voltages, and an additional circuit for controlling voltage of a node which is connected to the third drain, the second current source, and the first logic inverter circuit.

Exemplary embodiments of the present invention are described hereinafter with reference to the accompanying drawings.

The same or corresponding elements in the drawings and the following description are denoted with the same reference numerals, and a repeated detailed description is omitted as appropriate.

In the description of the embodiments, an N channel type MOSFET is referred to as an NMOS transistor and a P channel type MOSFET is referred to as a PMOS transistor. Moreover, a voltage comparison circuit according to embodiments may be incorporated in, for example, a CMOS integrated circuit, and may be applied to various products and equipment for a consumer use, industrial use, or the like.

### First Embodiment

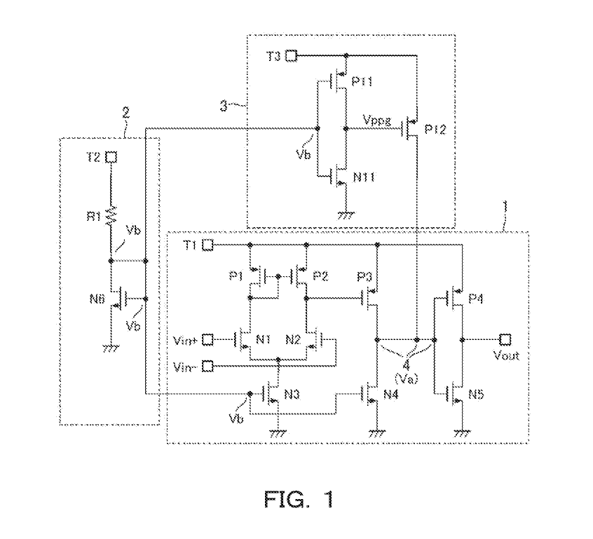

A voltage comparison circuit according to a first embodiment includes a voltage comparator (comparator) 1, a voltage generator (bias circuit) 2, and an additional circuit 3, as shown in FIG. 1. The bias circuit provides a voltage to the comparator and the additional circuit.

Each of these three circuits is described below with reference to FIG. 1.

First, the comparator 1 is described.

The comparator 1 comprises a CMOS integrated circuit. The comparator 1 compares two input voltages (Vin+ and Vin−) input to gates of NMOS transistors (N1 and N2) which form a differential pair, and outputs a high level or a low level as an output Vout based on a comparison result of these voltages.

The comparator 1 includes a differential amplifier circuit having NMOS transistors (N1, N2, and N3) and PMOS transistors (P1 and P2), an amplifier circuit having a PMOS transistor (P3) of which a gate is connected to an output node of the differential amplifier circuit and an NMOS transistor (N4) connected in series with the PMOS transistor (P3), and a first logic inverter circuit (first inverter) having a PMOS transistor (P4) and an NMOS transistor (N5) which are connected to an output node of the amplifier circuit.

Here, a power supply voltage Vdd0 (for example 1.8V) is supplied to a terminal T1 connected to a voltage source (not shown).

In addition, the NMOS transistors (N3 and N4) are current sources.

The two input voltages are input to the gates of the NMOS transistor (N1) and the NMOS transistor (N2) of the differential amplifier circuit (Vin+ is input to N1 and Vin− is input to N2). Each source of the NMOS transistor (N1) and the NMOS transistor (N2) of the differential amplifier circuit is connected in common to one end (source) of the NMOS transistor (N3) that is a current source. Another end (drain) of the NMOS transistor (N3) is connected to ground terminal (GND).

Respective drains of the NMOS transistors (N1 and N2) are connected to the respective PMOS transistors (P1 and P2) serving as loads. A pair of these two PMOS transistors (P1 and P2) forms a current mirror in which respective gates are connected each other. In addition, either one of drains of the PMOS transistors (P1 and P2) (in this example, P2) is connected to the gate of the PMOS transistor (P3). Voltage of the drain is input to the gate of the PMOS transistor (P3) as output of the differential amplifier circuit described above, and on-off control is performed.

The other drain of the PMOS transistors (P1 and P2) (in this example, P1) is short-circuited to its own gate. In addition, ends (sources) of the PMOS transistors (P1, P2, and P3) are connected to the terminal T1.

Here, another end (drain) of the PMOS transistor (P3) is connected to one end (drain) of the NMOS transistor (N4) serving as a current source, and also connected to gates of the PMOS transistor (P4) and the NMOS transistor (N5) which are included in the first inverter. The gate of the PMOS transistor (P4) and the gate of the NMOS transistor (N5) are connected in common. Another end (source) of the NMOS transistor (N4) is connected to the ground terminal (GND). A gate of the NMOS transistor (N4) and a gate of the NMOS transistor (N3) are connected in common, and a voltage Vb generated from the bias circuit 2 is provided to these gates.

Moreover, one end (source) of the PMOS transistor (P4) is connected to the terminal T1. In addition, one end (source) of the NMOS transistor (N5) is connected to the ground terminal (GND). Moreover, a node 4 in which another end (drain) of the PMOS transistor (P4) and another end (drain) of the NMOS transistor (N5) are connected is an output of the first inverter, and also an output of the comparator 1 (or the voltage comparison circuit). Here, the inverter may include multiple stages instead of a single stage.

The operation of the comparator 1 is as follows.

In the comparator 1, firstly, the input voltages (Vin+ and Vin−) input respectively to the NMOS transistors (N1 and N2) of the differential amplifier circuit are compared, output of the differential amplifier circuit is input to the amplifier circuit including the PMOS transistor (P3) and the NMOS transistor (N4), output of the amplifier circuit is input to the first inverter including the PMOS transistor (P4) and the NMOS transistor (N5), and inverter output as an output Vout of the voltage comparison circuit is retrieved.

Here, regarding the input voltages, Vin+ is a constant value and Vin− is a variable value. The values of both the voltages are to be compared during a certain time period.

A relationship between the input voltages and output is, typically, as follows. When a voltage difference (a magnitude relationship) of the input voltages is Vin+<Vin− (here, a difference between them, ΔVin, is large), the Vout is substantially equal to a ground voltage (GND=0V), which is a low level “L”. On the other hand, when the voltage difference between the input voltages is Vin+>Vin− (here, a difference between them, ΔVin, is large), the Vout is substantially equal to the power supply voltage (Vdd0), which is a high level “H”.

As mentioned above, the NMOS transistors (N3 and N4) are the current sources, and the voltage Vb generated in the bias circuit 2, which will be described later, is applied to each gate of the NMOS transistors (N3 and N4). That is, the NMOS transistors (N3 and N4) are connected in a current mirror configuration with a NMOS transistor (N6) of the bias circuit 2.

Next, the bias circuit 2 for generating the voltage Vb is described below.

The bias circuit 2 includes resistance (R1) and the NMOS transistor (N6) connected in series between a terminal T2 applied with the power supply voltage Vdd0 and the ground terminal (GND).

One end of the resistance (R1) is connected to the terminal T2. The other end of the resistance (R1) is connected to a gate of the NMOS transistor (N6) and one end (being located on opposite side of the ground terminal) of the NMOS transistor (N6).

A voltage of a node in which the resistance (R1) and the NMOS transistor (N6) are connected is applied to the NMOS transistors (N3 and N4) which are the current sources, as the voltage Vb generated by the bias circuit 2.

The terminal T2 in the bias circuit 2 is also connected to the external voltage source as well as the terminal T1 in the comparator 1, and the power supply voltage Vdd0 (for example, 1.8V) is supplied thereto.

In the bias circuit 2, when the power supply voltage Vdd0 increases and exceeds a threshold voltage (VthN) of the NMOS transistor (N6), the NMOS transistor (N6) is turned on and then the voltage Vb generated is to be set to a predetermined voltage value due to characteristics of the NMOS transistor (N6) and the resistance (R1). The voltage Vb is supplied to the NMOS transistors (N3 and N4) which are the current sources.

The additional circuit 3 will now be described below.

The additional circuit 3 includes a second logic inverter circuit (second inverter) comprising a PMOS transistor (P11) and an NMOS transistor (N11) and a PMOS transistor (P12) connected to an output of the second inverter.

The PMOS transistor (P11) is provided at a terminal T3 side. A terminal T3 is supplied with the power supply voltage Vdd0. The NMOS transistor (N11) is provided at a ground terminal (GND) side.

Gates of the PMOS transistor (P11) and the NMOS transistor (N11) are connected in common together.

Each gate is supplied with the voltage Vb generated from the bias circuit 2. An output voltage Vppg of the second inverter is applied to a gate of the PMOS transistor (P12).

One end (source) of the PMOS transistor (P12) is connected to the terminal T3 and another end (drain) is connected to an output node 4 of the differential amplifier circuit in the comparator 1 (i.e. an input of the first inverter (P4 and N5)).

The PMOS transistor (P12) is a switching element to control a voltage Va of the node 4 in which the drain of the PMOS transistor (P3) and the NMOS transistor (N4) that is a current source are connected, in the comparator 1. The gate of the PMOS transistor (P12) is applied with the voltage Vppg which controls the on/off thereof.

Here, it is necessary to set the voltage Vppg as “H” if NMOS(N6) turned on and the voltage Vb generated from the bias circuit 2 is supplied to each gate (common gate) of the NMOS transistor (N11) and the PMOS transistor (P11) those of which are included in the second inverter. Accordingly, it is necessary to determine a current capability ratio of the NMOS transistor (N11) to the PMOS transistor (P11) in a manner that each drain voltage is high level “H”, namely, Vdd0, or near Vdd0.

Moreover, the current capability ratio is determined in a manner that on resistance of the PMOS transistor (P12) in the additional circuit 3 is smaller than on resistance of the NMOS transistor (N4) that is the current source of the comparator 1.

Details on mutual relationship and the operation among the comparator 1, the bias circuit 2, and the additional circuit 3 of the voltage comparison circuit described above are explained hereinafter.

The relationship between the two input voltages in an initial state is defined to be Vin+<Vin− (Vin+ remains constant).

At first, when a voltage (<Vdd0, a voltage which is not yet reached at the power supply voltage Vdd0) becomes larger than the threshold voltage (VthN) of the NMOS transistor (N6) in a rise of the power supply voltage Vdd0 of the bias circuit 2, the NMOS transistor (N6) turns on. When the NMOS transistor (N6) turns on, the ground voltage (GND) is applied through the source of the NMOS (N6) and then the voltage Vb converges, to a predetermined voltage (<Vdd0) that is determined by a ratio on resistance of the NMOS transistor (N6) to the resistance (R1).

Thus, the voltage Vb generated in the bias circuit 2 rises with the rise of the power supply voltage Vdd0 and transitions to a voltage value which is lower than the Vdd0, for example, approximately 1.0V.

At this time, the NMOS transistor (N4) turns on due to the voltage Vb supplied to the gate of the NMOS transistor (N4) in the comparator 1. According to the first embodiment, the voltage Vb (1.0V<Vb<Vdd0, Vb≧threshold of N11 VthN) is also supplied to the gate of the NMOS transistor (N11) of the additional circuit 3 at the substantially same time as the NMOS transistor (N4) turns on. The output voltage Vppg of the second inverter then drops and the PMOS transistor (P12) turns on.

In addition, the power supply voltage Vdd0 is also supplied to each source of the PMOS transistors (P1, P2, and P3) of the comparator 1 at this time. Moreover, as described above, Vin+ and Vin− are applied to the gates of the NMOS transistors (N1 and N2), respectively, at the power on, and the NMOS transistors (N1 and N2) are in an on state.

Then, a voltage that is approximately a half of the power supply voltage Vdd0 is applied to the gates of the PMOS transistors (P1 and P2) according to, for example, capacitances of the PMOS transistor (P1), NMOS transistor (N1) and the like.

In addition, each of the PMOS transistors (P1 and P2) turns on in accordance with a relationship of voltages between the voltage applied to the gates of PMOS transistors (P1 and P2) and thresholds of the PMOS transistors (P1 and P2). However, the voltage levels change according to the capacitances, so it is not determined whether the PMOS transistors (P1 and P2) turn on or off, namely, they are in unstable states.

Accordingly, the gate voltage of the PMOS transistor (P3) is not also determined and the PMOS transistor (P3) is also in an unstable state, and thereby whether the voltage Va of the node 4 that is an output voltage of the PMOS transistor (P3) is a high level or a low level is not determined.

According to the embodiment, although the output voltage of the comparator 1 is not determined, the NMOS transistor (N4) of the comparator 1 and the PMOS transistor (P12) of the additional circuit 3 turn on at the substantially same time and thereby the voltage Va of the node 4 is to be determined according to an on resistance balance of the NMOS transistor (N4) and the PMOS transistor (P12) in their operation. According to the embodiment, on resistance of P12<on resistance of N4 is set and the power supply voltage Vdd0 is supplied to the node 4 through the PMOS transistor (P12).

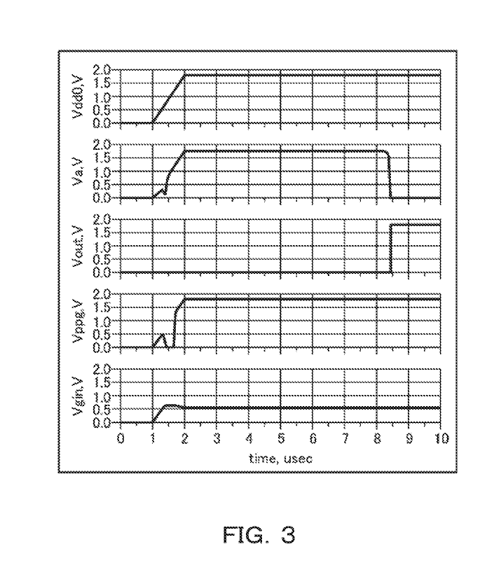

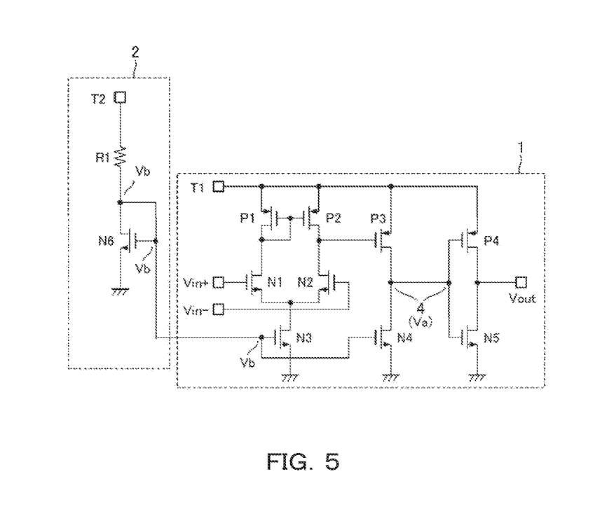

Now, consider that a voltage comparison circuit includes the comparator 1 and the bias circuit 2, but not the additional circuit 3 of FIG. 3, as shown in FIG. 5 which is a circuit diagram showing a comparative example, and a power supply voltage Vdd0 rises to operate in a same way as the first embodiment.

With this case, both of the PMOS transistor (P3) and the NMOS transistor (N4) are high impedance and a voltage Va of the node 4 is an intermediate voltage between 0V of the ground voltage (GND) and the power supply voltage Vdd0 (for example, 1.8V). An output Vout of the voltage comparison circuit, accordingly, is also an intermediate voltage between a high level “H” (=Vdd) and a low level “L” (=0V).

However, in the circuit according to the comparative example, the voltage Va of the output node 4 of the amplifier circuit (node at the input side of the inverter) temporarily drops when the power supply voltage Vdd0 rises and the NMOS transistor (N4) turns on. Due to this, the output Vout also becomes a high level “H” temporarily.

However, a relationship between two input voltages is Vin+<Vin− (a difference between both of them, ΔVin, is large), so a current flows into a Vin− side. That is, the NMOS transistor (N2) is ON, and the NMOS transistor (N1) is OFF. At this time, the gate of the PMOS transistor (P3) is supplied with a voltage (≧threshold VthP of P3) which is determined according to an impedance ratio of the NMOS transistors (N2 and N3) to the PMOS transistor (P2), and then the PMOS transistor (P3) also turns on just a little later than the NMOS transistor (N4) turns on. This allows the voltage Va to rise again and the output Vout to be stabilized appropriately at a low level “L”.

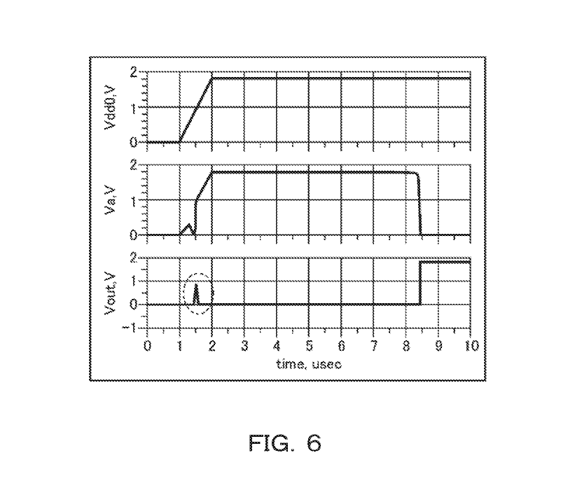

FIG. 6 is a timing chart showing changes in each of the power supply voltage Vdd0, the voltage Va of the node 4 and the output Vout of the voltage comparison circuit with time. The chart shows simulation results when specific circuit parameters are set.

As clearly shown in FIG. 6, in the output Vout, a voltage rise can be seen temporarily, as shown within a dashed line. The voltage rise is caused by a change in the output (voltage drop) of the amplifier when the power supply voltage Vdd rises.

That is, although the output Vout is expected to be a low level “L” or 0V until the relationship of the two input voltage becomes Vin+>Vin−, a phenomenon in which the voltage of the output Vout rises temporarily when the voltage Va of the node 4 temporarily drops as described above can be seen. This means that the output of the voltage comparison circuit is temporarily wrong, which is not expected.

When a logical circuit is configured by utilizing such a voltage comparison circuit that voltage of output Vout rises temporarily, malfunctions may be caused in other circuits using the output Vout.

In contrast, the voltage comparison circuit, according to the first embodiment, includes the additional circuit 3 and is set to be on resistance of P12<on resistance of N4 as described above, so the power supply voltage Vdd0 is supplied to the node 4 of the comparator 1 through the PMOS transistor (P12).

Accordingly, it is possible to prevent the drop of the voltage Va of the node 4 as seen in the comparative example and remain the output Vout of the voltage comparison circuit stable at a low level “L”.

Then, when the voltage Vb of the bias circuit 2 which has set to be the value (for example, 1V<Vdd0) as mentioned above, a node voltage Vppg rises in association with a current capability ratio of the NMOS transistor (N11) and the PMOS transistor (P11) and the PMOS transistor (P12) turns off.

The voltage Va of the node 4, accordingly, is not to be affected by the PMOS transistor (P12) and Vout can be determined depending on only the input voltages of the voltage comparison circuit and characteristics of the voltage comparison circuit.

Subsequently, when the relationship of the two input voltage becomes Vin+>Vin−, a current flows into the NMOS transistor (N1) side and the NMOS transistor (N2) turns off. This causes a gate voltage of the PMOS transistor (P3) to become equal to Vdd0 and the PMOS transistor (P3) turns off.

Accordingly, Va becomes equal to the ground voltage (GND). As a result, Vout transitions from a low level “L” to a high level “H”.

As described above, by including the additional circuit 3 having the PMOS transistor (P12) of which the on resistance is smaller than the NMOS transistor (N4), the voltage comparison circuit according to the first embodiment can prevent the voltage Va of the output node 4 of the amplifier circuit in the comparator 1 from dropping when the power supply voltage Vdd rises and the output can remain stable accordingly.

This further eliminates risk of causing malfunctions in other circuits that use the output of the voltage comparison circuit according to the first embodiment.

### Second Embodiment

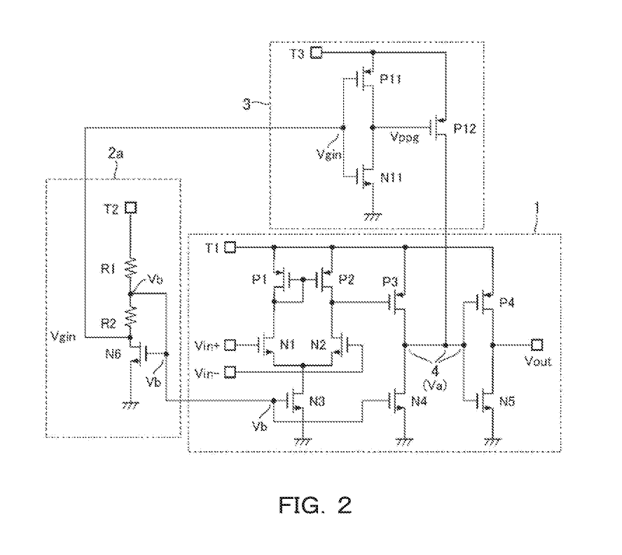

A second embodiment will now be described with reference to a circuit diagram of FIG. 2.

The second embodiment includes a bias circuit which is different from the bias circuit 2 used in the first embodiment.

In the bias circuit 2 used in the first embodiment, the drain and the gate of the NMOS transistor (N6) are directly short-circuited, whereas in a bias circuit 2a of the second embodiment, resistance (R2) is added between a drain (one end being located on opposite side of GND) of an NMOS transistor (N6) and resistance (R1), and a gate of the NMOS transistor (N6) is connected between the resistance (R1) and the resistance (R2) In addition, one end (drain) of the NMOS transistor (N6) is applied with a predetermined voltage Vgin and another end (source) is connected to the ground terminal (GND).

The voltage Vgin is also to be supplied to a common gate of a PMOS transistor (P11) and a NMOS transistor (N11) of an additional circuit 3 as well as the first embodiment. Here, a voltage is supplied as the voltage Vgin where a power supply voltage Vdd0 supplied to a terminal T2 is dropped due to combined resistance of the resistance (R1) and the resistance (R2) and characteristics of the NMOS transistor (N6).

Next, the operation of the second embodiment is described briefly hereinafter.

In the first embodiment, an input voltage to the gates of the PMOS transistor (P11) and the NMOS transistor (N11) of the second inverter of the additional circuit 3 is Vb, whereas in the second embodiment it is Vgin(<Vb).

Accordingly, the voltage Vgin generated from the bias circuit 2a is supplied to the gates of the NMOS transistor (N11) and the PMOS transistor (P11) after a voltage value of Vb is set (in the example described above, 1.0V), and drain currents flowing through the NMOS transistor (N11) and the PMOS transistor (P11) are lower than that in the first embodiment, and this results in reducing power consumption.

FIG. 3 is a timing chart showing changes in each of the power supply voltage Vdd0, voltage Va of a node 4 and output Vout with time according to the second embodiment. The timing chart of FIG. 3 further shows Vppg and Vgin. The voltage Vgin generated in the bias circuit 2a of the second embodiment rises when the power supply voltage Vdd0 rises, as well as the voltage Vb in the first embodiment, and it transitions to, for example, approximately 0.5V which is lower than Vdd0 (for example, 1.8V) and Vb (for example, 1.0V).

FIG. 3 is also simulation results as well as the case of FIG. 6.

As shown in FIG. 3, the voltage Va of the node 4 momentarily drops upon the rise of the power supply voltage Vdd0, however a dropped amount is a very little because the additional circuit 3 having the PMOS transistor (P12) is provided as described in the first embodiment. For this reason, according to the embodiment, the effect as described in FIG. 6 does not occur to the output voltage Vout of the voltage comparison circuit as shown in FIG. 3.

In addition, the timing chart is substantially same as that of the first embodiment described above.

### Third Embodiment

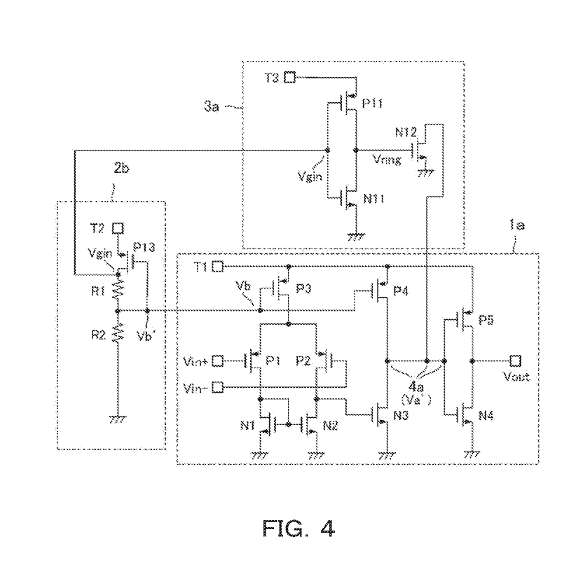

A third embodiment is described with reference to a circuit diagram of FIG. 4.

In a configuration of the third embodiment, an NMOS differential input (N1 and N2) in the comparator 1 of the second embodiment is replaced with a PMOS differential input (P1 and P2). Along with this replacement, configurations and connections among other NMOS and PMOS transistors in a comparator of the second embodiment are also replaced (1a).

The NMOS differential input is used to compare voltages that are relatively high, whereas the PMOS differential input is used to compare voltages that are relatively low.

Here, NMOS transistors (N1 and N2) are loads, and PMOS transistors (P3 and P4) are current sources to be connected to a terminal T1 supplied with a voltage Vdd0. In addition, gates of the PMOS transistors (P3 and P4) are connected in common, and a voltage Vb′ generated from a bias circuit 2b is applied thereto. One end of an NMOS transistor (N3) configuring an amplifier circuit with the PMOS transistor (P4) is connected to ground (GND) terminal, and a gate thereof is connected to either one of the NMOS transistors (N1 and N2).

A voltage Va′ of an output node 4a in an amplifier circuit is controlled by an additional circuit 3a. One end of an NMOS transistor (N12) being a switching element is connected to the ground terminal (GND), and another end is connected to the node 4a.

Accordingly, in the third embodiment, on resistance of the NMOS transistor (N12) being the switching element is set to be lower than on resistance of the PMOS transistor (P4).

In addition, a configuration of an inverter including a PMOS transistor (P11) and NMOS transistor (N1) is substantially same as that in the case of the second embodiment. The inverter is connected to a gate of the NMOS transistor (N12) and provides a voltage Vnng to the gate.

Moreover, in the configuration of the embodiment, the NMOS transistor (N6) of the bias circuit 2a and the PMOS transistor (P12) of the additional circuit 3 in the second embodiment are also replaced with a PMOS transistor (P13) of the bias circuit 2b, and the NMOS transistor (N12) of the additional circuit 3a, respectively.

As described above, to prevent the voltage Va of the node 4 from dropping temporarily (in the cases of the embodiments 1 and 2) or the voltage Va′ of the node 4a from rising temporarily (in the case of the embodiment 3), when the power supply voltage Vdd0 rises and the voltage level transitions and to stabilize the output Vout of the voltage comparison circuit are common to the first, the second, and the third embodiments.

Therefore, it can be possible to provide a system with high reliability by utilizing a voltage comparator (comparator) of each embodiment in integrated into, for example, an oscillator of a digital circuit or a digital circuit system.

The embodiment described above is provided as an example and not intended to limit the scope of the invention.

Moreover, the NMOS transistors and the PMOS transistors in each of the first to third embodiments do not need to be the same ones even though the same numerals are given. They shall be appropriately and suitably designed in each embodiment.

Indeed, the novel embodiments described herein may possibly be embodied in various other forms; and furthermore, various omissions, substitutions and changes may be made by referring to the embodiment described herein without being beyond the scope of the invention. The embodiments are included in the scope or summary of the invention and also included in the invention as claimed in the claims and the equivalents thereof.

What is claimed is:

1. A voltage comparison circuit comprising:
a first MOS transistor of a first conductivity type including a first gate applied with a first input voltage, a first source, and a first drain;
a second MOS transistor of the first conductivity type including a second gate applied with a second input voltage which is compared with the first input voltage, a second source electrically connected to the first source, and a second drain;
a first current source connected in common to the first source and the second source;
loads individually connected to the first drain and the second drain;
a third MOS transistor of a second conductivity type including a third gate connected to either one of the first drain and the second drain, a third source, and a third drain;
a second current source connected to the third drain;
a first logic inverter circuit connected to the third drain and generating a logic output based on a voltage difference between the first input voltage and the second input voltage; and
an additional circuit for controlling voltage of a node connected to the second current source and the first logic inviter circuit.

2. The voltage comparison circuit according to claim 1, wherein the first and the second current sources are MOS transistors and a voltage generated in a bias circuit is applied to gates of the first and second current sources by using a current mirror.

3. The voltage comparison circuit according to claim 1, wherein the first and the second MOS transistors are N channel type MOS transistors and the third MOS transistor and the loads are P channel type MOS transistors.

4. The voltage comparison circuit according to claim 1, wherein the first and the second MOS transistors are P channel type MOS transistors and the third MOS transistor and the loads are N channel type MOS transistors.

5. The voltage comparison circuit according to claim 1, wherein the additional circuit comprises a second logic inverter circuit and a fourth MOS transistor of which a gate is connected to an output of the second logic inverter circuit.

6. The voltage comparison circuit according to claim 5, wherein the first and the second current sources are MOS transistors and on resistance of the fourth MOS transistor is lower than on resistance of the MOS transistor of the second current source.

7. The voltage comparison circuit according to claim 2, wherein the bias circuit is provided between a power supply terminal and ground terminal, includes first resistance and a fifth MOS transistor which are connected in series, has a node to which either a source or a drain of the fifth MOS transistor, one end of the first resistance, and a gate of the fifth MOS transistor are connected, and supplies voltage generated at the node to the first and the second current sources.

8. The voltage comparison circuit according to claim 7, further comprising:
second resistance provided between either the source or the drain of the fifth MOS transistor and one end of the first resistance, wherein a voltage generated at a node which is located between the first resistance and the second resistance and connected to the gate of the fifth MOS transistor is applied to the first and the second current sources.
